(19) United States
(12) Patent Application Publication
(10) Pub. No.: US 2024/0047476 A1
(43) Pub. Date: Feb. 8, 2024

(54) DISPLAY PANEL AND MANUFACTURING METHOD THEREOF

(71) Applicant: TCL CHINAL STAR OPTOELECTRONICS TECHNOLOGY CO., LTD., Shenzhen (CN)

(72) Inventor: Mingyao Wang, Shenzhen (CN)

(73) Assignee: TCL CHINAL STAR OPTOELECTRONICS TECHNOLOGY CO., LTD., Shenzhen (CN)

(21) Appl. No.: 17/598,285

(22) PCT Filed: Feb. 26, 2021
(86) PCT No.: PCT/CN2021/078011

§ 371 Date: Sep. 26, 2021

(30) Foreign Application Priority Data
Jan. 19, 2021 (CN) 202110070064.9

(51) Int. Cl. H01L 27/12

(52) U.S. Cl. CPC H01L 27/1244; H01L 27/1288

(57) ABSTRACT

A display panel and a manufacturing method are provided. The display panel includes: a first metal layer including at least one first metal line; an insulating layer covering the first metal layer; and a second metal layer including at least one second metal line overlappingly crossing the at least one first metal line. The at least one first metal line includes a planarization part and an overlapping part overlapping the at least one second metal line. Along a first direction, a thickness of the overlapping part is less than a thickness of the planarization part.

### FIELD

The present disclosure relates to a field of display technologies, and more particularly, to a display panel and a manufacturing method thereof.

### BACKGROUND

In display panel designs, different metal layers are used to transmit different signals between different lines overlappingly crossing each other. As shown in FIG. 1 and FIG. 2, taking a display panel having a double-layer metal, which is commonly used nowadays, as an example. When an upper-layer metal line 3 crosses a bottom-layer metal line 1, a problem of breakage or abnormality usually occurs on a climbing part of the upper-layer metal line 3 because a bottom-layer metal is overly thick or a taper angle a between a bottom surface of the bottom-layer metal and a lateral surface of the bottom-layer metal is overly great.

Regarding the technical issues: because the problem of breakage or abnormality occurs on the climbing part of the upper-layer metal line 3, panels display defects such as a dark line, which significantly affects quality and a yield rate of the panels. Moreover, with improvement of resolution and a refresh rate of display panels, a loading of the display panels is increased. To reduce the loading of the display panels, a metal layer is designed to be increasingly thicker. However, this increases a possibility of breakage occurring on the climbing part of the upper-layer metal line.

### SUMMARY

In a first aspect, the present disclosure provides a display panel, comprising:
a first metal layer comprising at least one first metal line;
an insulating layer covering the first metal layer; and
a second metal layer covering the insulating layer and comprising at least one second metal line overlapping the at least one first metal line;
wherein the first metal line comprises a planarization part not overlapping the second metal line and an overlapping part overlapping the second metal line, and a thickness of the overlapping part is less than a thickness of the planarization part along a first direction;
an area of a cross-section of the overlapping part is equal to an area of a cross-section of the planarization part; and
a distance between an edge of the overlapping part and an edge of the second metal line is greater than or equal to 3 μm along an extending direction of the at least one first metal line.

In some embodiments of the present disclosure, a ratio between the thickness of the planarization part and the thickness of the overlapping part ranges from 1.5 to 2.

In some embodiments of the present disclosure, the first metal layer comprises a plurality of first metal lines parallel to each other; the second metal layer comprises a plurality of second metal lines parallel to each other; and the first metal lines are perpendicular to the second metal lines.

In some embodiments of the present disclosure, the first metal layer is a gate line metal layer, and the at least one first metal line is a gate line; and the second metal layer is a data line metal layer, and the at least one second metal line is a data line.

In some embodiments of the present disclosure, the first metal layer is a data line metal layer, and the at least one first metal line is a data line; and the second metal layer is a gate line metal layer, and the at least one second metal line is a gate line.

In some embodiments of the present disclosure, a material of the first metal layer is same as a material of the second metal layer.

In some embodiments of the present disclosure, the first metal layer and the second metal layer comprise one or at least two of Mo, Al, Cu, or W.

In some embodiments of the present disclosure, the insulating layer comprises one or two of SiNx or SiOx.

In a second aspect, the present disclosure provides a display panel, comprising:
a first metal layer comprising at least one first metal line;
an insulating layer covering the first metal layer; and
a second metal layer covering the insulating layer and comprising at least one second metal line overlapping the at least one first metal line;
wherein the at least one first metal line comprises a planarization part not overlapping the at least one second metal line and an overlapping part overlapping the at least one second metal line, and a thickness of the overlapping part is less than a thickness of the planarization part along a first direction.

In some embodiments of the present disclosure, an area of a cross-section of the overlapping part is equal to an area of a cross-section of the planarization part.

In some embodiments of the present disclosure, a ratio between the thickness of the planarization part and the thickness of the overlapping part ranges from 1.5 to 2.

In some embodiments of the present disclosure, a distance between an edge of the overlapping part and an edge of the at least one second metal line is greater than or equal to 3 μm along an extending direction of the at least one first metal line.

In some embodiments of the present disclosure, the first metal layer comprises a plurality of first metal lines parallel to each other; the second metal layer comprises a plurality of second metal lines parallel to each other; and the first metal lines are perpendicular to the second metal lines.

In some embodiments of the present disclosure, the first metal layer is a gate line metal layer, and the at least one first metal line is a gate line; and the second metal layer is a data line metal layer, and the at least one second metal line is a data line.

In some embodiments of the present disclosure, the first metal layer is a data line metal layer, and the at least one first metal line is a data line; and the second metal layer is a gate line metal layer, and the at least one second metal line is a gate line.

In some embodiments of the present disclosure, a material of the first metal layer is same as a material of the second metal layer.

In some embodiments of the present disclosure, the first metal layer and the second metal layer comprise one or at least two of Mo, Al, Cu, or W.

In a third aspect, the present disclosure provides a method of manufacturing a display panel, comprising following steps:
providing a first metal layer, and partly patterning the first metal layer to form at least one first metal line comprising a planarization part and an overlapping part, wherein an area of a cross-section of the overlapping part is equal to an area of a cross-section of the planarization part, a thickness of the planarization part is greater than a thickness of the overlapping part, and a width of the planarization part is less than a width of the overlapping part;
forming an insulating layer on the first metal layer; and
forming a second metal layer on the insulating layer, and patterning the second metal layer to form at least one second metal line overlapping the overlapping part.

In some embodiments of the present disclosure, in the step of providing the first metal layer, and partly patterning the first metal layer to form the at least one first metal line comprising the planarization part and the overlapping part, the method comprises following steps:
providing the first metal layer;
coating a photoresist on the first metal layer to form a photoresist layer;
performing an exposure process and a developing process on the photoresist layer with a semi-transparent mask to form a secondary photoresist layer comprising a first photoresist part and a second photoresist part, wherein a thickness of the first photoresist part is greater than a thickness of the second photoresist part;
performing a first etching process on the secondary photoresist layer;
performing an ashing process on the secondary photoresist layer after the first etching process to completely remove the second photoresist part, expose the first metal layer, and form the at least one first metal line;
performing a second etching process on the at least one first metal line to form the overlapping part; and
stripping off the first photoresist part to form the planarization part.

In some embodiments of the present disclosure, the semi-transparent mask is a half-tone mask or a gray-tone mask.

Regarding the beneficial effects: in the present disclosure, a thickness of an overlapping part of a first metal line is less than a thickness of a planarization part of the first metal line. Therefore, a climbing angle of a second metal line overlappingly crossing the first metal line is reduced. As such, a possibility of breakage or abnormity occurring on a climbing part of the second metal line is reduced, which is beneficial for improving quality of display panels and increasing a yield rate.

### DESCRIPTION OF DRAWINGS

FIG. 1 is a schematic view showing a bottom-layer metal line overlapping an upper-layer metal line in a conventional display panel.

FIG. 2 is a structural schematic view showing the conventional display panel.

FIG. 3 is a structural schematic view showing a display panel provided by an embodiment of the present disclosure.

FIG. 4 is a structural schematic view showing a first metal line provided by an embodiment of the present disclosure.

FIG. 5 is a perspective view showing the first metal line overlapping a second metal line provided by the embodiment of the present disclosure.

FIG. 6 is a plan view showing the first metal line overlapping the second metal line provided by the embodiment of the present disclosure.

FIG. 7 is a flowchart showing a method of manufacturing a display panel provided by an embodiment of the present disclosure.

FIG. 8 is a flowchart showing a step S100 provided by the embodiment of the present disclosure.

FIG. 9 is schematic view showing changes in structure of a first metal layer during manufacturing processes provided by the embodiment of the present disclosure.

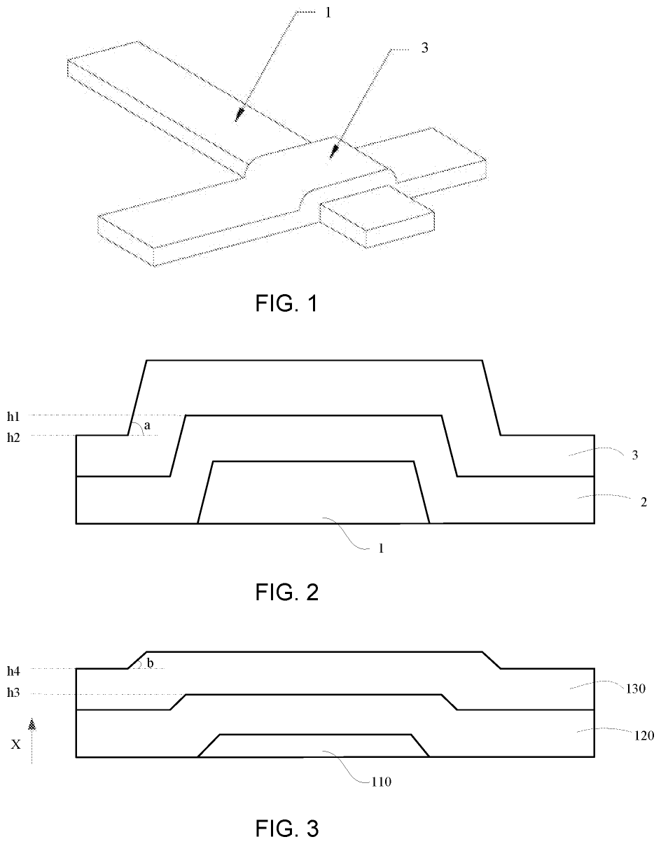

### DETAILED DESCRIPTION

Hereafter technical solutions provided by embodiments of the present disclosure will be clearly and completely described in conjunction with drawings.

In the following descriptions, details are listed for the purpose of illustration. It should be noted that those skilled in the art may realize the present disclosure without using the specific details. In other embodiments, conventional structures and processes are not be illustrated in detail to prevent the illustration of the present disclosure from being complicated due to unnecessary details. Therefore, exemplary embodiments are consistent with principles and features, which are interpreted broadly, disclosed by the present disclosure but shall not be regarded as limitations of the present disclosure.

Embodiments of the present disclosure provide a display panel and a manufacturing method thereof, which are described in detail as follows.

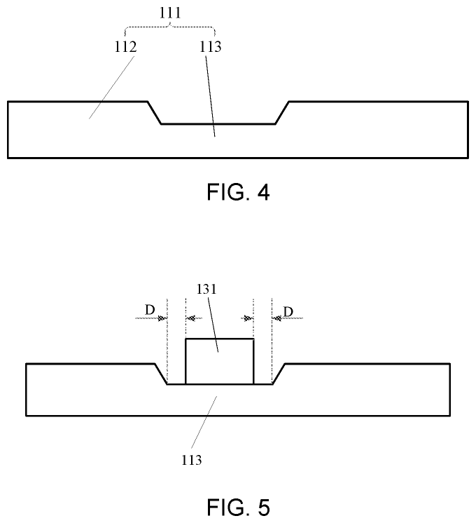

As shown in FIG. 3 and FIG. 4, an embodiment of the present disclosure provides a display panel 100, wherein the display panel 100 includes:
a first metal layer 110, wherein the first metal layer 110 includes at least one first metal line 111;
an insulating layer 120, wherein the insulating layer 120 covers the first metal layer 110; and
a second metal layer 130, wherein the second metal layer 130 covers the insulating layer 120 and includes at least one second metal line 131 overlapping the first metal line 111.

Wherein, the first metal line 111 includes a planarization part 112 and an overlapping part 113 overlapping the second metal line 131. Along a first direction X, a thickness of the overlapping part 113 is less than a thickness of the planarization part 112.

It should be noted that the first direction X denotes a direction perpendicular to an extending direction of the first metal line 111 and an extending direction of the second metal line 131.

In the first metal line 111 of the present disclosure, a thickness of the first metal line 111 is less than the thickness of the planarization part 112, thereby reducing a climbing angle of the second metal line 131 overlappingly crossing the first metal line 111. Therefore, a possibility of breakage or abnormity occurring on a climbing part of the second metal line 131 is reduced, which is beneficial for improving quality of the display panel 100 and increasing a yield rate.

In the present embodiment, a material of the first metal layer 110 and a material of the second metal layer 130 include one of Mo, Al, Cu, or W, or include an alloy composed of at least two of the above metals. A material of the insulating layer 120 includes SiNx, SiOx, or a combination composed of the above two materials.

It should be understood that the material of the first metal layer 110 and the material of the second metal layer 130 may be same or different. To reduce cost and simply manufacturing processes, preferably, the material of the first metal layer 110 and the material of the second metal layer 130 are same.

Specifically, as shown in FIG. 2, in conventional display panels, a height h1 of a protrusion formed on an area of an insulating layer 2 corresponding to a bottom-layer metal line 1 is greater than a height h2 an area where an upper-layer metal line 3 crosses the bottom-layer metal line 1. Therefore, the upper-layer metal line 3 is prone to be broken at the area where an upper-layer metal line 3 crosses a bottom-layer metal line 1. Furthermore, as shown in FIG. 2, an angle between a bottom surface of an upper-layer metal and a lateral-inclined surface of the upper-layer metal is relatively great, which further increases a possibility of breakage occurring on a climbing part of the upper-layer metal line 3.

As shown in FIG. 3, in the display panel 100 of the present embodiment, a height h3 of a protrusion formed on an area of the insulating layer 120 corresponding to the first metal layer 110 is less than a height h4 of an area where the second metal layer 130 crosses the first metal layer 110. Therefore, the second metal line 131 of the second metal layer 130 is not easy to be broken at a climbing part. Furthermore, as shown in FIG. 3, by making the thickness of the overlapping part 113 of the first metal line 111 less than the thickness of the planarization part 112 of the first metal line 111, an angle b between a bottom surface of the second metal layer 130 and a lateral-inclined surface of the second metal layer 130 can also be reduced. Therefore, a possibility of breakage occurring on the climbing part of the second metal line 131 can be further reduced.

In one embodiment of the present disclosure, the thickness of the overlapping part 113 is 50% to 80% of the thickness of the planarization part 112. It should be understood that the thickness of the overlapping part 113 can be adjusted according to an actual situation and is not limited to the above range.

Furthermore, to prevent a display effect of the display panel 100 from being affected due to an increase in resistance of the first metal line 111 when the thickness of the overlapping part 113 is reduced, in the present embodiment, an area of a cross-section of the overlapping part 113 is equal to an area of a cross-section of the planarization part 112. Because of this arrangement, the resistance of the first metal line 111 remains unchanged. In addition, resistance of the overlapping part 113 and resistance of the planarization part 112 may be set to be same, thereby enhancing resistance uniformity and further improving quality of the display panel 100.

It the present embodiment, it should be understood that the thickness of the overlapping part 113 is less than the thickness of the planarization part 112 to reduce a possibility of breakage or abnormity occurring on the climbing part of the second metal line 131. Furthermore, the area of the cross-section of the overlapping part 113 is equal to the area of the cross-section of the planarization part 112 to make the resistance of the first metal line 111 remain unchanged. Therefore, as shown in FIG. 5, a width of the overlapping part 113 is greater than a width of the planarization part 112 along a second direction Y. Wherein, the second direction Y is perpendicular to the first direction X.

Furthermore, in some embodiments of the present disclosure, a ratio between the thickness of the planarization part 112 and the thickness of the overlapping part 113 ranges from 1.5 to 2. Wherein, the ratio between the thickness of the planarization part 112 and the thickness of the overlapping part 113 is relevant to the thickness of the first metal line 111. Specifically, when the thickness of the first metal line 111 is greater than or equal to 7000 Å, the ratio between the thickness of the planarization part 112 and the thickness of the overlapping part 113 is 2. When the thickness of the first metal line 111 is greater than or equal to 5000 Å, the ratio between the thickness of the planarization part 112 and the thickness of the overlapping part 113 is 1.5.

It should be understood that a length of the overlapping part 113 is relevant to a width of the second metal line 131. The wider the second metal line 131, the longer the overlapping part 113. In some embodiments of the present disclosure, the length of the overlapping part 113 is greater than the width of the second metal line 131 along the extending direction of the first metal line 111.

Specifically, as shown in FIG. 5, a distance D between an edge of the overlapping part 113 and an edge of the second metal line 131 is greater than or equal to 3 μm.

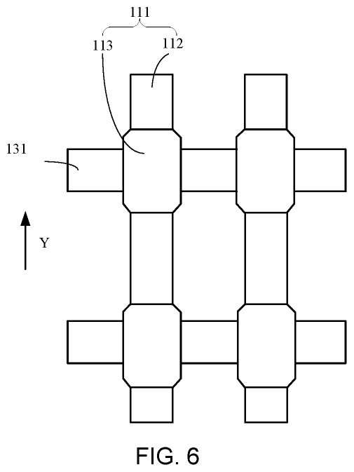

In the present embodiment, as shown in FIG. 6, the first metal layer 110 includes a plurality of first metal lines 111 parallel to each other.

Furthermore, the second metal layer 130 includes a plurality of second metal lines 131 parallel to each other.

It should be understood that the first metal lines 111 overlap the second metal lines 131, thereby defining a plurality of pixel areas.

Preferably, the first metal lines 111 are perpendicular to the second metal lines 131.

Because of the above arrangements, more pixel areas can be defined on the display panel 100 having a same area, thereby improving quality of the display panel 100.

Furthermore, in the present embodiment, the first metal layer 110 is a gate line metal layer, the first metal lines 111 are gate lines, the second metal layer 130 is a data line metal layer, and the second metal lines 131 are data lines.

In other embodiments of the present disclosure, the first metal layer 110 is the data line metal layer, the first metal lines 111 are the data lines, the second metal layer 130 are the gate line metal layer, and the second metal lines 131 are gate lines.

It should be understood that the first metal layer 110 and the second metal layer 130 may also be other metal layers, and are not limited to the gate line metal layer and the data line metal layer. The first metal layer 110 and the second metal layer 130 may be any metal layer which needs to cross a line in the display panel 100.

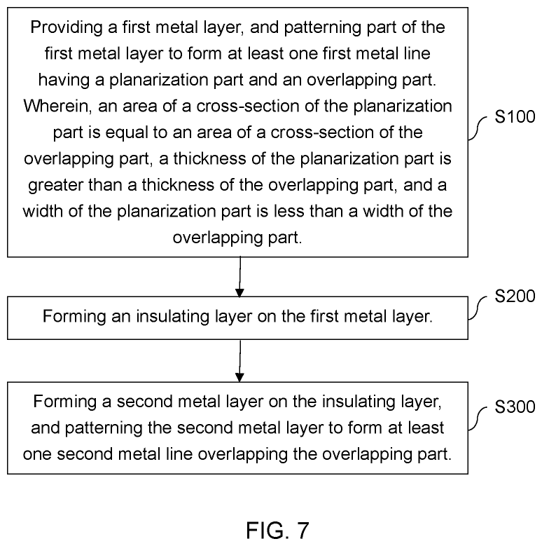

An embodiment of the present disclosure further provides a method of manufacturing a display panel, as shown in FIG. 7, specifically including following steps:

Step S100, providing a first metal layer 110, and patterning part of the first metal layer 110 to form at least one first metal line 111 having a planarization part 112 and an overlapping part 113. Wherein, an area of a cross-section of the planarization part 112 is equal to an area of a cross-section of the overlapping part 113, a thickness of the planarization part 112 is greater than a thickness of the overlapping part 113, and a width of the planarization part 112 is less than a width of the overlapping part 113.

Step S200, forming an insulating layer 120 on the first metal layer 110.

Step S300, forming a second metal layer 130 on the insulating layer 120, and patterning the second metal layer 130 to form at least one second metal line 131 overlapping the first metal line 111.

Wherein, the first metal line 111 includes the planarization part 112 and the overlapping part 113 overlapping the second metal line 131. Along a first direction X, a thickness of the overlapping part 113 is less than a thickness of the planarization part 112.

In the present disclosure, the thickness of the overlapping part 113 of the first metal line 111 is less than the thickness of the planarization part 112 of the first metal line 111. Therefore, a climbing angle of the second metal line 131 overlappingly crossing the first metal line 111 is reduced. As such, a possibility of breakage or abnormity occurring on a climbing part of the second metal line 131 is reduced, which is beneficial for improving quality of the display panel 100 and increasing a yield rate.

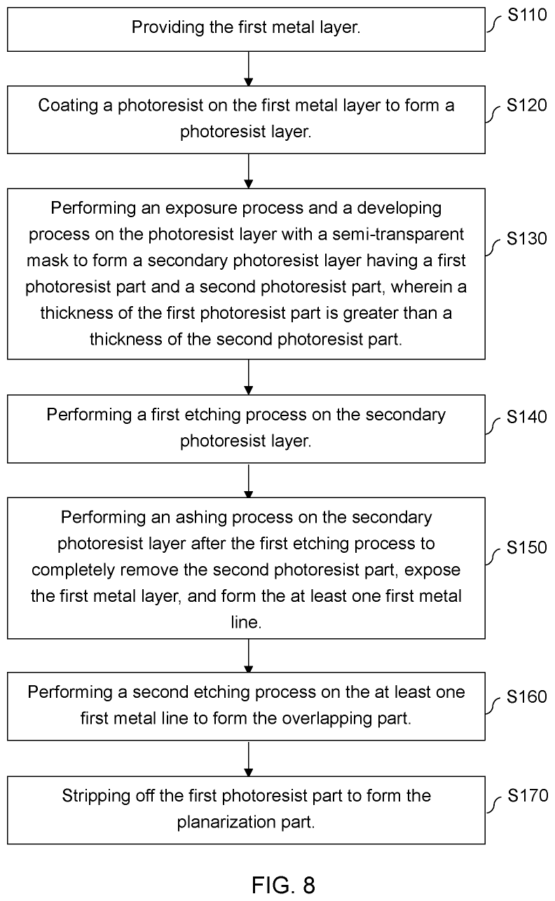

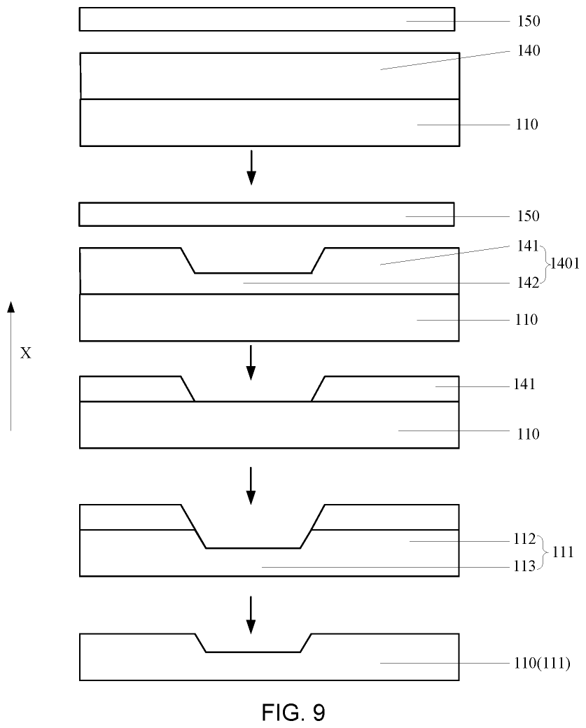

Furthermore, as shown in FIG. 8 and FIG. 9, the step S100 specifically includes following steps:

Step S110, providing the first metal layer 110.

Step S120, coating a photoresist on the first metal layer 110 to form a photoresist layer 140.

Step S130, performing an exposure process and a developing process on the photoresist layer 140 with a semi-transparent mask 150 to form a secondary photoresist layer 1401 having a first photoresist part 141 and a second photoresist part 142, wherein a thickness of the first photoresist part 141 is greater than a thickness of the second photoresist part 142.

It should be noted that the semi-transparent mask 150 may be a gray-tone mask (GTM) or a half-tone mask (HTM) A purpose of using the GTM or HTM is to increase an exposure amount of the photoresist layer 140 corresponding to the overlapping part 113, thereby forming the first photoresist part 141 and the second photoresist part 142 which have different thicknesses.

Wherein, a purpose of performing the exposure process is to transfer a mask pattern to the photoresist layer 140 by an exposure source. A purpose of performing the developing process is to remove an exposed area of the photoresist layer 140 or an unexposed area of the photoresist layer 140, thereby patterning the photoresist layer 140.

Step S140, performing a first etching process on the secondary photoresist layer 1401. Wherein, the first etching process is a wet-etching process. By etching the secondary photoresist layer 1401, the mask pattern is transferred to the secondary photoresist layer 1401.

Step S150, performing an ashing process on the secondary photoresist layer 1401 after the first etching process to completely remove the second photoresist part 142, expose the first metal layer 110, and form the at least one first metal line 111. By performing the ashing process on the secondary photoresist layer 1401, the second photoresist part 142 and residues due to the ashing process can be further removed, thereby increasing a manufacturing accuracy.

Step S160, performing a second etching process on the at least one first metal line 111 to form the overlapping part 113. Wherein, the second etching process is a wet-etching process or a dry-etching process.

Step S170, stripping off the first photoresist part 141 to form the planarization part 112.

Wherein, along the first direction X, a thickness of the overlapping part 113 is less than a thickness of the planarization part 112.

It should be noted that the dry-etching process is to expose a surface of a to-be-etched substance to air, thereby generating plasma, wherein a physical reaction or a chemical reaction occurs between the plasma penetrating the photoresist layer 140 and the surface of the to-be-etched substance, thereby removing a material, which is exposed to air, on the surface of the to-be-etched substance.

The wet-etching process is to remove a material on a surface of a to-be-etched substance with a liquid chemical reagent. In an actual application, an etching method can be determined according to multiple factors such as cost, etching rate, etc.

In summary, in the present embodiment, the thickness of the overlapping part 113 of the first metal line 111 is less than the thickness of the planarization part 112 of the first metal line 111, thereby reducing a climbing angle of the second metal line 131 overlappingly crossing the first metal line 111. Therefore, a possibility of breakage or abnormity occurring on the climbing part of the second metal line 131 is reduced, which is beneficial for improving quality of the display panel 100 and increasing a yield rate. Furthermore, in the present embodiment, the area of the cross-section of the overlapping part 113 is equal to the area of the cross-section of the planarization part 112, thereby making resistance of the first metal line 111 remain unchanged. In addition, resistance of the overlapping part 113 may be set to be same as resistance of the planarization part 112, thereby improving resistance uniformity and further enhancing quality of the display panel 100.

A display panel and a manufacturing method thereof have been described in detail by the above embodiments, which illustrates principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

What is claimed is:

1. A display panel, comprising:
a first metal layer comprising at least one first metal line;
an insulating layer covering the first metal layer; and
a second metal layer covering the insulating layer and comprising at least one second metal line overlapping the at least one first metal line;
wherein the at least one first metal line comprises a planarization part not overlapping the at least one second metal line and an overlapping part overlapping the at least one second metal line, and a thickness of the overlapping part is less than a thickness of the planarization part along a first direction;
an area of a cross-section of the overlapping part is equal to an area of a cross-section of the planarization part; and
a distance between an edge of the overlapping part and an edge of the at least one second metal line is greater than or equal to 3 μm along an extending direction of the at least one first metal line.

2. The display panel of claim 1, wherein a ratio between the thickness of the planarization part and the thickness of the overlapping part ranges from 1.5 to 2.

3. The display panel of claim 2, wherein the first metal layer comprises a plurality of first metal lines parallel to each other;
the second metal layer comprises a plurality of second metal lines parallel to each other; and
the first metal lines are perpendicular to the second metal lines.

4. The display panel of claim 1, wherein the first metal layer is a gate line metal layer, and the at least one first metal line is a gate line; and
the second metal layer is a data line metal layer, and the at least one second metal line is a data line.

5. The display panel of claim 1, wherein the first metal layer is a data line metal layer, and the at least one first metal line is a data line; and
the second metal layer is a gate line metal layer, and the at least one second metal line is a gate line.

6. The display panel of claim 1, wherein a material of the first metal layer is same as a material of the second metal layer.

7. The display panel of claim 1, wherein the first metal layer and the second metal layer comprise one or at least two of Mo, Al, Cu, or W.

8. The display panel of claim 1, wherein the insulating layer comprises one or two of SiNx or SiOx.

9. A display panel, comprising:
a first metal layer comprising at least one first metal line;
an insulating layer covering the first metal layer; and
a second metal layer covering the insulating layer and comprising at least one second metal line overlapping the at least one first metal line;
wherein the first metal line comprises a planarization part not overlapping the at least one second metal line and an overlapping part overlapping the at least one second metal line, and a thickness of the overlapping part is less than a thickness of the planarization part along a first direction.

10. The display panel of claim 9, wherein an area of a cross-section of the overlapping part is equal to an area of a cross-section of the planarization part.

11. The display panel of claim 9, wherein a ratio between the thickness of the planarization part and the thickness of the overlapping part ranges from 1.5 to 2.

12. The display panel of claim 9, wherein a distance between an edge of the overlapping part and an edge of the at least one second metal line is greater than or equal to 3 μm along an extending direction of the at least one first metal line.

13. The display panel of claim 12, wherein the first metal layer comprises a plurality of first metal lines parallel to each other;
the second metal layer comprises a plurality of second metal lines parallel to each other; and
the first metal lines are perpendicular to the second metal lines.

14. The display panel of claim 9, wherein the first metal layer is a gate line metal layer, and the at least one first metal line is a gate line; and
the second metal layer is a data line metal layer, and the at least one second metal line is a data line.

15. The display panel of claim 9, wherein the first metal layer is a data line metal layer, and the at least one first metal line is a data line; and
the second metal layer is a gate line metal layer, and the at least one second metal line is a gate line.

16. The display panel of claim 9, wherein a material of the first metal layer is same as a material of the second metal layer.

17. The display panel of claim 9, wherein the first metal layer and the second metal layer comprise one or at least two of Mo, Al, Cu, or W.

18. A method of manufacturing a display panel, comprising following steps:
providing a first metal layer, and partly patterning the first metal layer to form at least one first metal line comprising a planarization part and an overlapping part, wherein an area of a cross-section of the overlapping part is equal to an area of a cross-section of the planarization part, a thickness of the planarization part is greater than a thickness of the overlapping part, and a width of the planarization part is less than a width of the overlapping part;
forming an insulating layer on the first metal layer; and
forming a second metal layer on the insulating layer, and patterning the second metal layer to form at least one second metal line overlapping the overlapping part.

19. The method of claim 18, wherein in the step of providing the first metal layer, and partly patterning the first metal layer to form the at least one first metal line comprising the planarization part and the overlapping part, the method comprises following steps:
providing the first metal layer;
coating a photoresist on the first metal layer to form a photoresist layer;
performing an exposure process and a developing process on the photoresist layer with a semi-transparent mask to form a secondary photoresist layer comprising a first photoresist part and a second photoresist part, wherein a thickness of the first photoresist part is greater than a thickness of the second photoresist part;
performing a first etching process on the secondary photoresist layer;
performing an ashing process on the secondary photoresist layer after the first etching process to completely remove the second photoresist part, expose the first metal layer, and form the at least one first metal line;
performing a second etching process on the at least one first metal line to form the overlapping part; and
stripping off the first photoresist part to form the planarization part.

20. The method of claim 19, wherein the semi-transparent mask is a half-tone mask or a gray-tone mask.
